(19) United States
(12) Patent Application Publication
(10) Pub. No.: US 2003/0128520 A1
(43) Pub. Date: Jul. 10, 2003

(54) Packaging structure with heat slug

(76) Inventor: Yaw-Yuh Yang, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,633

(22) Filed: Nov. 5, 2002

(30) Foreign Application Priority Data
Jan. 7, 2002 (TW) 91100093

(51) Int. Cl. H05K 7/20

(52) U.S. Cl. 361/704; 257/706

(57) ABSTRACT

A packaging structure comprises a substrate, a chip, a plurality of bonding wires, a heat slug, and a molding compound. The chip is attached and electrically connected onto the substrate. The heat slug includes a concave cover element outwardly extended into a flange, the concave cover element including an outer heat dissipating surface around which a ringed projection is formed. The heat slug is mounted onto the substrate via attaching the flange onto the substrate surface while the concave cover element covers the chip. The molding compound encapsulates the substrate surface, the chip, and the flange of the heat slug while leaving the outer heat dissipating surface of the heat slug externally exposed. Via the ringed projection, the molding compound, when injected to encapsulate the chip, is prevented from flowing over the outer heat dissipating surface of the heat slug.

### CROSS REFERENCE TO RELATED APPLICATIONS

This application claims the priority benefit of Taiwan application serial no. 91100093, filed Jan. 7, 2002.

### BACKGROUND OF INVENTION

1. Field of the Invention

The invention relates generally to packaging structures provided with heat slugs. More particularly, the invention relates to a packaging structure provided with a heat slug that prevents excessive coverage of molding compound being injected over the heat slug.

2. Description of the Related Art

With the development of electronics technology, integrated circuit (IC) chips process faster while incorporating high-density circuitry in smaller structures. The above improvements require overcoming various problems such as heat dissipation. To dissipate the heat irradiated from the chip, a heat slug is usually mounted over the packaged chip.

Referring to FIG. 1 through FIG. 3, various cross-sectional views show the fabrication of a packaging structure provided with a conventional heat slug. As shown in FIG. 1, a starting structure of the packaging structure comprises a substrate 120 that includes a surface 122 where a die pad 126 and a plurality of contact pads 124 are defined. The contact pads 124 are disposed around the die pad 126. A chip 110, via a rear surface 114 thereof, is attached onto the die pad 126 of the substrate 120. A plurality of bonding pads 116, defined on an active surface 112 of the chip 110, are electrically connected to the contact pads 124 by means of bonding wires 130.

As shown in FIG. 1 and FIG. 4, a heat slug 140 is further placed over the substrate 120 and the chip 110. The heat slug 140 includes a cover 142 that peripherally extends into a flange 144. The cover 142 is formed in a dish shape including a concavity. The flange 144 extends according to a rectangular shape. The flange 144 is provided with a plurality of protrusions 146 that are located at each corner of the flange 144. The protrusions 146 are bonded onto the surface 122 of the substrate 120 via an adhesive 149 formed on the end surfaces 148 of the protrusions 146, thereby attaching the heat slug 140 onto the substrate 120, the concavity of the cover 142 being oriented toward the chip 110.

As shown in FIG. 2, the assembled structure 102 is placed in a mold 150 provided with a mold cavity 152. More particularly, the assembled structure 102 is arranged with an outer heat dissipating surface 141 of the cover 142 tightly abutting against a inner surface 154 of the mold cavity 152 while the mold 150 is pressed on the substrate surface 122.

As shown in FIG. 2 and FIG. 3, a molding compound 160 is injected into the mold cavity 152 to encapsulate the chip 110, the bonding wires 130, the substrate 120, and the flange 144 and protrusions 146, while the outer heat dissipating surface 141 is externally exposed. Heat dissipation is thereby achieved via the outer heat dissipating surface 141 of the heat slug 140.

As shown in FIG. 2 and FIG. 4, however the outer heat dissipating surface 141 is tightly abutted against the inner surface 154 of the mold cavity 152, a portion 162 of the molding compound 160 being injected may flow over the outer heat dissipating surface 141 of the heat slug 140. This negatively affects the aesthetic aspect of the final packaging structure and, furthermore, adversely hampers heat dissipation. An additional polishing is usually required to remove the portion 162 of the molding compound 160. This additional processing step negatively increases the fabrication cost and the fabrication time.

### SUMMARY OF INVENTION

An aspect of the invention is therefore to provide a packaging structure that includes a heat slug which heat dissipation is not hampered by the coverage of a molding compound thereon.

To accomplish the above and other objectives, a packaging structure provided with a heat slug according to the invention comprises a substrate, a chip, a plurality of bonding wires, a heat slug, and a molding compound. The substrate includes a substrate surface where a die pad and a plurality of contact pads are defined, the contact pads being defined around the die pad. The chip includes an active surface and a rear surface, a plurality of bonding pads being defined on the active surface. The chip, via the rear surface thereof, is attached onto the die pad while the bonding wires electrically connect the contact pads of the substrate to the bonding pads of the chip. The heat slug includes a concave cover element that peripherally extends into a flange. A plurality of protrusions project from the flange along the direction of the concavity of the concave cover element. The heat slug is mounted onto the substrate via attaching the protrusions of the flange onto the substrate surface while the concave cover element covers the chip. The molding compound encapsulates the substrate surface, the chip, the bonding wires, and the flange and protrusions of the heat slug while leaving the outer heat dissipating surface of the heat slug externally exposed.

In accordance with the above and other objectives of the invention, a method of fabricating a packaging structure with heat slug is further provided. The method comprises providing a starting structure including a substrate, and a chip. The substrate includes a substrate surface where a die pad and a plurality of contact pads are defined, the contact pads being defined around the die pad. The chip includes an active surface and a rear surface, a plurality of bonding pads being defined on the active surface. The chip, via the rear surface thereof, is attached onto the die pad, while the bonding wires electrically connect the contact pads of the substrate to the bonding pads of the chip. A heat slug is further provided. The heat slug includes a concave cover element that peripherally extends into a flange. A plurality of protrusions project from the flange along the direction of the concavity of the concave cover element. The heat slug is mounted onto the substrate via attaching the protrusions to the substrate surface while the concave cover element covers the chip. The assembled structure is mounted in a mold that includes a mold cavity with an inner surface, the mold being pressed onto the substrate surface in a manner to have the ringed projection tightly abut against the inner surface of the mold cavity. A molding compound is injected into the mold cavity to encapsulate the substrate surface, the chip, the bonding wires, and the flange and protrusions of the heat slug. The ringed projection prevents the molding compound being injected from flowing over the outer heat dissipating surface of the heat slug, heat dissipation is thereby effectively achieved via the outer heat dissipating surface of the heat slug.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 through FIG. 3 are cross-sectional views of the fabrication of a packaging structure provided with a conventional heat slug;

FIG. 4 is a top view of the packaging structure of FIG. 3, wherein FIG. 3 is a cross-sectional view taken along the section I-I of FIG. 4;

FIG. 5 through FIG. 7 are cross-sectional views illustrating the fabrication of a packaging structure provided with a heat slug according to an embodiment of the invention; and

FIG. 8 is a top view of the packaging structure of FIG. 7, wherein FIG. 7 is a cross-sectional taken along the section II-II of FIG. 7.

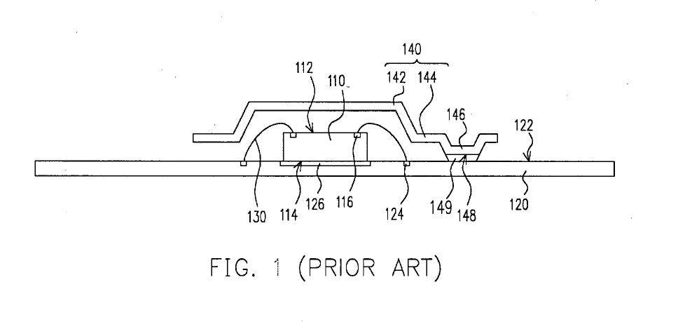

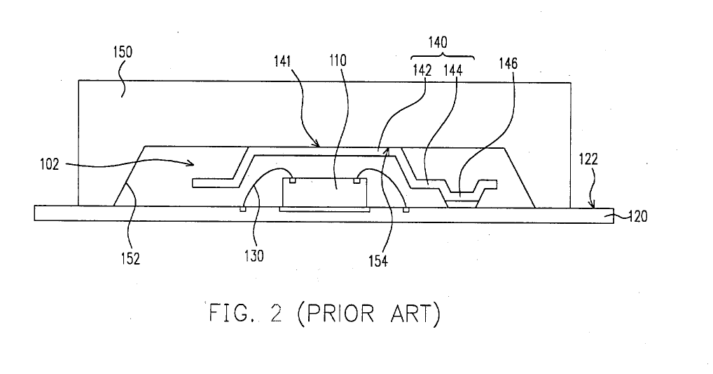

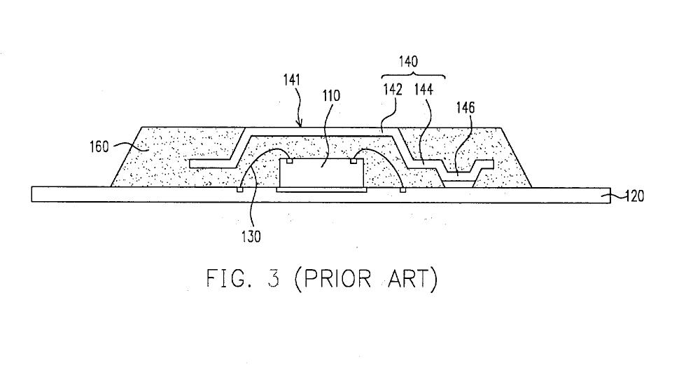

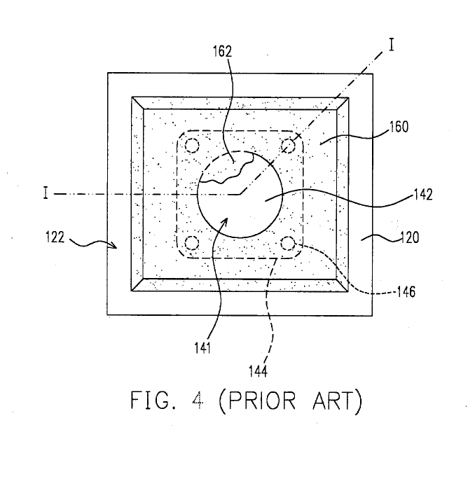

### DETAILED DESCRIPTION

The following detailed description of the embodiments and examples of the present invention with reference to the accompanying drawings is only illustrative and not limiting. Wherever possible in the following description and accompanying drawings, like reference numerals and symbols will refer to like elements and parts unless otherwise described.

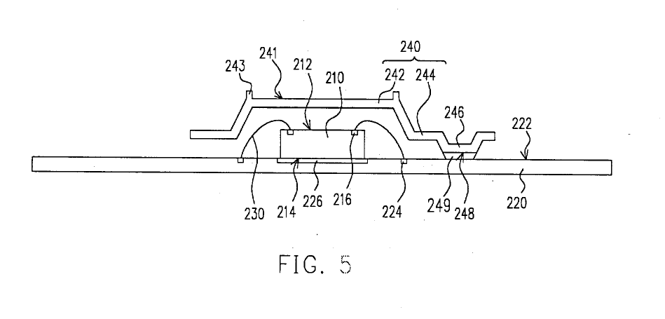

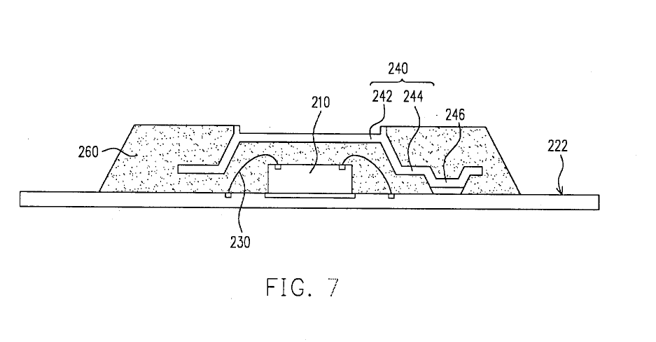

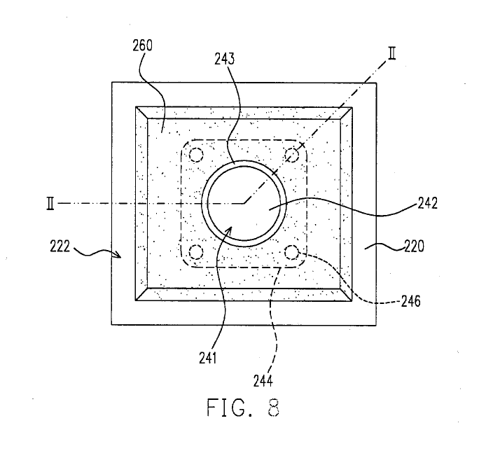

Referring now to FIG. 5 through FIG. 8, various views schematically illustrate the fabrication process of a semiconductor package provided with a heat slug according to an embodiment of the invention. FIG. 5 through FIG. 7 are cross-sectional views schematically showing the packaging structure in different stages of the fabrication process, FIG. 7 being a cross-sectional view taken along the section line II-II of the top view of FIG. 8.

As shown in FIG. 5, a starting structure of the packaging structure comprises a substrate 220 that includes a substrate surface 222 where a die pad 226 and a plurality of contact pads 224 are defined. The contact pads 224 are disposed, for example, around the die pad 226. A chip 210, via a rear surface 214 thereof, is attached onto the die pad 226 of the substrate 220. A plurality of bonding pads 216, defined on an active surface 212 of the chip 210, are electrically connected to the contact pads 224 by means of bonding wires 230.

As shown in FIG. 5 and FIG. 8, a heat slug 240 is further placed over the substrate 220 and the chip 210. The heat slug 240 includes a cover 242 that peripherally extends into a flange 244. The cover 242 is formed in, for example, a dish shape including a concavity. The flange 244 extends according to, for example, a rectangular shape. The flange 244 is provided with a plurality of protrusions 246 that may be, for example, vis-à-vis each corner of the flange 244. The protrusions 246 project along a direction similar to the direction of the concavity of the cover 242, and respectively terminate into end surfaces 248 that are approximately coplanar to one another. The cover 242 of the heat slug 240 further externally includes an outer heat dissipating surface 241 around which a ringed projection 243 is formed. The ringed projection 243 may be placed, for example, in a manner to surround the outer heat dissipating surface 241 of the heat slug. A height of the ringed projection 243 is about 10 μm to about 20 μm, and a width of the ringed projection 243 is about 100 μm to about 500 μm. The ringed projection 243 may be formed in any adequate shape such as annular shape (as illustrated), for example. The cover 242, the flange 244, the ringed projection 243, and the protrusions 246 may be formed into a single body.

As shown in FIG. 5, the protrusions 246 are bonded to the substrate surface 222 via, for example, an adhesive 249, thereby attaching the heat slug 240 to the substrate 220 with the concavity of the cover 242 being oriented toward the chip 210.

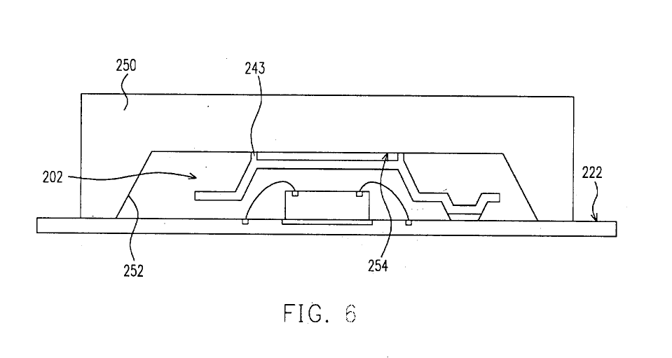

As shown in FIG. 6, the formed structure 202 is arranged in a mold 250, the heat slug 240 being placed within a mold cavity 252 of the mold 250. When the mold 250 is pressed against the substrate surface 222, an inner surface 254 of the mold cavity 252 tightly abuts against the ringed projection 243 of the heat slug 240.

As shown in FIG. 6 and FIG. 7, a molding compound 260 is injected in the mold cavity 252 to encapsulate the chip 210, the bonding wires 230, the flange 244, and the protrusions 246, leaving the outer heat dissipating surface 241 and a part of the ringed projection 243 externally exposed. Heat irradiated from the chip 210 is thereby effectively dissipated via the externally exposed outer heat dissipating surface 241 of the heat slug 240.

When the mold 250 is pressed over the substrate surface 222, because the contact surface of the ringed projection 243 with the inner surface 254 of the mold cavity 252 is relatively small, a tight contact there between can be thereby achieved. As a result, the molding compound 260 being injected into the mold cavity 252 is prevented from flowing over the outer heat dissipating surface 241 of the cover 242. Those skilled in the art would readily appreciate that the invention as exemplary described above can be implemented with various types of packaging structures. For example, the invention can be also favorably implemented with well-known flip-chip type packaging structures.

As described above, the invention therefore provides a packaging structure with an embedded heat slug that can effectively dissipate heat. Effective thermal dissipation is achieved through the outer heat dissipating surface of the heat slug that is externally exposed. Via placing a ringed projection around the outer heat dissipating surface of the heat slug dedicated to heat dissipation, the molding compound, when injected to encapsulate the packaging structure, is thereby prevented from flowing over the outer heat dissipating surface of the heat slug. The entire outer heat dissipating surface of the heat slug being externally exposed without coverage of molding compound thereon, heat dissipation is thereby effectively achieved without the inconveniences of the prior art.

It should be apparent to those skilled in the art that other structures that are obtained from various modifications and variations of various parts of the above-described structures of the invention would be possible without departing from the scope and spirit of the invention as illustrated herein. Therefore, the above description of embodiments and examples only illustrates specific ways of making and performing the invention that, consequently, should cover variations and modifications thereof provided they fall within the inventive concepts as defined in the following claims.

1. A packaging structure comprising:
a substrate, having a substrate surface;
a chip, attached onto the substrate surface and electrically connected to the substrate;
a heat slug, attached onto the substrate surface in a manner to cover the chip, the heat slug including an outer heat dissipating surface around which a ringed projection is formed; and
a molding compound, encapsulating the chip, the substrate surface, and a portion of the heat slug while externally exposing the outer heat dissipating surface of the heat slug.

2. The packaging structure of claim 1, wherein the heat slug peripherally extends into a flange.

3. The packaging structure of claim 2, wherein the flange is provided with a plurality of protrusions through which the heat slug is attached to the substrate surface.

4. The packaging substrate of claim 2, wherein the flange is formed into a single body with the heat slug.

5. The packaging structure of claim 1, wherein a height of the ringed projection is about 10 μm to about 20 μm.

6. The packaging structure of claim 1, wherein a width of the ringed projection is about 100 μm to about 500 μm.

7. A heat slug for a packaging structure that is externally encapsulated by means of a molding compound, comprising an outer heat dissipating surface around which a ringed projection is formed for preventing the molding compound from covering the outer heat dissipating surface of the heat slug.

8. The heat slug of claim 7, wherein the heat slug peripherally extends into a flange.

9. The heat slug of claim 8, wherein the packaging structure includes a substrate, and the flange of the heat slug is provided with a plurality of protrusions through which the heat slug is attached to a surface of the substrate.

10. The heat slug of claim 8, wherein the heat slug and the flange are formed into a single body.

11. The heat slug of claim 7, wherein a height of the ringed projection is about 10 μm to about 20 μm.

12. The heat slug of claim 7, wherein a width of the ringed projection is about 100 μm to about 500 μm.

13. A method of fabricating a packaging structure provided with a heat slug, the method comprising:
providing a substrate onto which a chip is mounted and electrically connected;
providing a heat slug including an outer heat dissipating surface around which is formed a ringed projection, the heat slug peripherally extending into a flange;
mounting the heat slug onto the substrate via attaching the flange of the heat slug onto the substrate, the heat slug being placed over the substrate in a manner to cover the chip;
mounting the substrate with the heat slug in a mold, the mold including a mold cavity that has an inner surface, the heat slug being received in the mold cavity with the ringed projection tightly abutting against the inner surface of the mold cavity; and
injecting a molding compound into the mold cavity to encapsulate the chip, the substrate surface, and the flange of the heat slug while leaving the outer heat dissipating surface of the heat slug exposed.

14. The method of claim 13, wherein a height of the ringed projection is about 10 μm to about 20 μm.

15. The method of claim 13, wherein a width of the ringed projection is about 100 μm to about 500 μm.

16. The method of claim 13, wherein the ringed projection prevents the molding compound being injected from flowing over the outer heat dissipating surface of the heat slug.
